(19) United States
(12) Patent Application Publication
(10) Pub. No.: US 2005/0275059 A1
(43) Pub. Date: Dec. 15, 2005

(54) Isolation trench arrangement

(76) Inventors: Ricardo Pablo Mikalo, Waltersdorf (DE); Christoph Ludwig, Langebruck (DE); Pascal Deconinck, Dresden (DE); Jan-Malte Schley, Muenchen (DE); Mark Isler, Dresden (DE); Jens-Uwe Sachse, Dresden (DE)

Correspondence Address: SLATER & MATSIL LLP, 17950 PRESTON ROAD, SUITE 1000, DALLAS, TX, 75252, US

(21) Appl. No.: 11/145,509

(22) Filed: Jun. 3, 2005

(30) Foreign Application Priority Data
Jun. 14, 2004 (DE) 10 2004 028 679.5

(51) Int. Cl. H01L 29/00; H01L 21/76

(52) U.S. Cl. 257/510; 438/424

(57) ABSTRACT

Isolation trench arrangement, which isolates adjacent semiconductor structures (1), (2), an isolation trench (3) being formed in such a way that it penetrates from a substrate surface into the substrate volume (0) and has at least one insulating substance (20) and at least one conductive substance (21), and the conductive substance (21) is electrically conductively connected to the substrate (0) via an electrically conductive connection (22).

This application claims priority to German Patent Application 10 2004 028 679.5, which was filed Jun. 14, 2004, and is incorporated herein by reference.

### TECHNICAL FIELD

The invention relates to an isolation trench arrangement and a method for fabricating an isolation trench arrangement of this type.

### BACKGROUND

Trench isolation (e.g., STI or Shallow Trench Isolation) is understood to be the lateral isolation of adjacent transistors or of other active regions by trenches that are etched into the monocrystalline silicon and filled with insulating material. Such an isolation is necessary primarily in the case of components having a high transistor density, such as, e.g., memories, since the crosstalk between the components increases as a result of the small spacing. Particularly at structure widths of less than 180 nm, trench isolation gains acceptance over the widespread LOCOS (Local Oxidation of Silicon) method for the isolation of active semiconductor components since it has better scalability and, at the same time, takes up less chip area.

FIG. 1 illustrates a cross section through a trench for the isolation of adjacent semiconductor structures, which is known from the prior art. A trench 3 is etched into a substrate 0. A part of the active region of a first transistor 1 can be seen on the right of the trench 3. The active region is isolated from the active region of a second transistor 2 by the trench 3. The trench 3 is covered with a silicon oxide layer 4 (SiO₂) produced by thermal oxidation and is filled with an insulating oxide 5, such as, e.g., silicon oxide. A gate oxide 6 is additionally arranged above the active regions 1, 2 and the filled trench 3. Situated above that is a gate electrode, for the driving and selection of the transistors, which is not illustrated here for the sake of simplification.

With increasing miniaturization of memory cells, edge effects, that is to say effects that occur at the transitions (edges) between the active regions and the trenches, become more and more important. In the case where edge effects were still negligible for the overall behavior of the cell at large widths of the active regions of, e.g., 1 μm, the influence becomes apparent to a much greater extent at small active widths of approximately 100 nm.

FIG. 2 shows a further cross section through a trench 3, which isolates the active region of a first transistor 1 from the active region of a second transistor 2. The equipotential lines 10, such as occur in a trench 3 and at the edges 7 of the active structures 1, 2 at a gate voltage of 9.5 V, are additionally shown. The field distortion at the upper edges 7 of the trench and the deep penetration of the field into the trench 3 are clearly visible.

The penetration of the electric field at the edges 7 into the active regions 1, 2 means that the threshold voltage of the transistors is lowered locally there. The transistors conduct at these locations more readily than in the center of the active regions. Since the threshold voltage Vₜₕ of a transistor is composed of the integral of the local threshold voltages over the entire active region of the transistor, the field inhomogeneity at the edges of the active regions leads to a lowering of the threshold voltage Vₜₕ of the transistor.

At large widths of the active regions (e.g., 1 μm), the zones at which edge effects occur are negligibly small in comparison with the rest of the active regions. They, therefore, also make only a small contribution to the threshold voltage Vₜₕ of the transistor and can generally be disregarded. At small widths of the active regions, such as less than 100 nm, for instance, the zones at which edge effects occur constitute a significant part of the total active area, however. The fall in the threshold voltage at the edge regions influences the threshold voltage Vₜₕ of the transistors to a greater extent than is the case at large active widths. This decrease in the threshold voltage Vₜₕ as the active widths decrease is referred to as “width roll-off”.

In addition to a reduction of the threshold voltage Vₜₕ, in the case of memory cells, the inhomogeneous electric field leads to an inhomogeneous injection of charge carriers into the memory layer under the control gate. Since charge carriers have thus already been injected at the edge of the active regions, but not yet in the center of the active regions, a homogeneous programming and erasure of cells is no longer possible. This charge injection inhomogeneity caused by the edge effects leads to problems particularly in the storage and erasure of cells that are operated with high programming voltages of approximately 9 to 10 V, such as, e.g., NROM or floating gate cells.

By way of the threshold voltage Vₜₕ, the field distortion in the edge regions affects almost all essential electrical properties of the transistors. The dependence of the threshold voltage on the width of the active region becomes more and more important with increasing miniaturization of the active widths since process-dictated variations in the widths of the active regions lead directly to fluctuations of the threshold voltage Vₜₕ and thus to variations in the electrical properties. However, it is precisely in the case of arrangements having very many cells, such as, e.g., a 1 Gbit memory, that large fluctuations of the electrical properties between individual cells are undesirable.

### SUMMARY OF THE INVENTION

Therefore, embodiments of the invention specify an arrangement and a method for isolating adjacent semiconductor structures by means of a trench that make it possible to minimize the fluctuations of the threshold voltage Vₜₕ and other electrical quantities particularly in the case of active semiconductor structures having a small active width.

In one aspect, this goal is achieved according to embodiments of the invention by virtue of the fact that the isolation trench has both insulating and conductive substances.

By virtue of the fact that the fluctuations of the threshold voltages Vₜₕ are reduced, the semiconductor structures can advantageously be manufactured with larger tolerances, which makes it possible to use inexpensive manufacturing techniques. As an alternative, the invention makes it possible to produce smaller structures with the same manufacturing tolerance that leads to an increase in the memory density. If manufacturing tolerances and structures remain the same, then the invention enables a higher yield by virtue of the lower fluctuations. Furthermore, the invention makes it possible to homogenize the electric field over the trench and the active regions, thereby achieving a homogeneous charge injection.

Further details and refinements of the invention are specified in the subclaims.

In accordance with one development of the invention, the insulating substance is formed in the form of a layer covering the trench walls. Layers of this type can readily be produced by means of the customary manufacturing technologies and have excellent isolation properties.

In accordance with a further development, the insulating substance covers not only the trench walls but also the trench bottom in the form of layers.

In a preferred embodiment, the trench lined with the insulating substance is filled with a conductive substance. In this way, it is possible for adjacent semiconductor structures to be isolated, but without electric fields being able to penetrate deep into the trench. This leads to a homogeneous field profile with the associated advantages.

The conductive substance advantageously has a defined potential. What is thereby achieved is that electric fields in the conductive substance are matched to the field distribution in the active regions. Charging by induction is simultaneously avoided.

In accordance with one development, the ground potential corresponds to the defined potential of the conductive substance. What is thereby achieved is that the threshold voltage is distributed uniformly over the trench and the active regions.

In an advantageous manner, the conductive substance is electrically conductively connected to the substrate. This may be effected via a cutout in the insulation layer at the trench bottom. This means that no additional contacts and terminals are necessary.

The conductive substance expediently comprises conductive polysilicon. The latter may be correspondingly doped. With the aid of customary manufacturing methods, it is thus possible to realize largely conformal depositions even in narrow trenches.

The insulating substance is advantageously an oxide layer. Such layers can be fabricated in a simple manner.

In a preferred development, the semiconductor structures are active components such as e.g. transistors or memory cells.

Preferably, a trench is fashioned in the substrate between the semiconductor structures. The trench is lined with an insulating substance, such as, e.g., an oxide layer, and filled with a conductive substance, such as, e.g., conductive polysilicon.

In an advantageous manner, a trench is fashioned in the substrate between the semiconductors structures, the trench walls are covered with an insulating substance, such as, e.g., an oxide layer and the trench is filled with a conductive substance such as, e.g., conductive polysilicon, the conductive substance being electrically conductively connected to the substrate at the bottom of the trench.

The invention is explained in more detail below using an exemplary embodiment with the aid of the drawings.

### DESCRIPTION OF THE DRAWINGS

For a more complete understanding of the present invention, and the advantages thereof, reference is now made to the following descriptions taken in conjunction with the accompanying drawing, in which:

FIG. 1 shows an arrangement for isolating adjacent semiconductor structures by means of a trench according to the prior art;

FIG. 2 shows equipotentials in the trench and in the active regions in an arrangement for isolating adjacent semiconductor structures by means of a trench according to the prior art;

FIG. 3 shows an arrangement for isolating adjacent semiconductor structures by means of a trench, in which the trench has insulating and conductive substances in a substrate; and

FIG. 4 shows a detail from FIG. 3 with the distribution of the electric field being specified.

The following list of reference symbols can be used in conjunction with the figures:

| | |
|---|---|
| 0 | Substrate |
| 1 | Active region of a first transistor |
| 2 | Active region of a second transistor |
| 3 | Trench |
| 4 | Oxide layer |
| 5 | Electrically insulating trench filling |
| 6 | Gate oxide |
| 7 | Edge between trench and active region |
| 10 | Equipotential lines |
| 20 | Oxide layer |
| 21 | Electrically conductive trench filling |
| 22 | Electrically conductive connection |
| 30 | Electric field lines |

### DETAILED DESCRIPTION OF ILLUSTRATIVE EMBODIMENTS

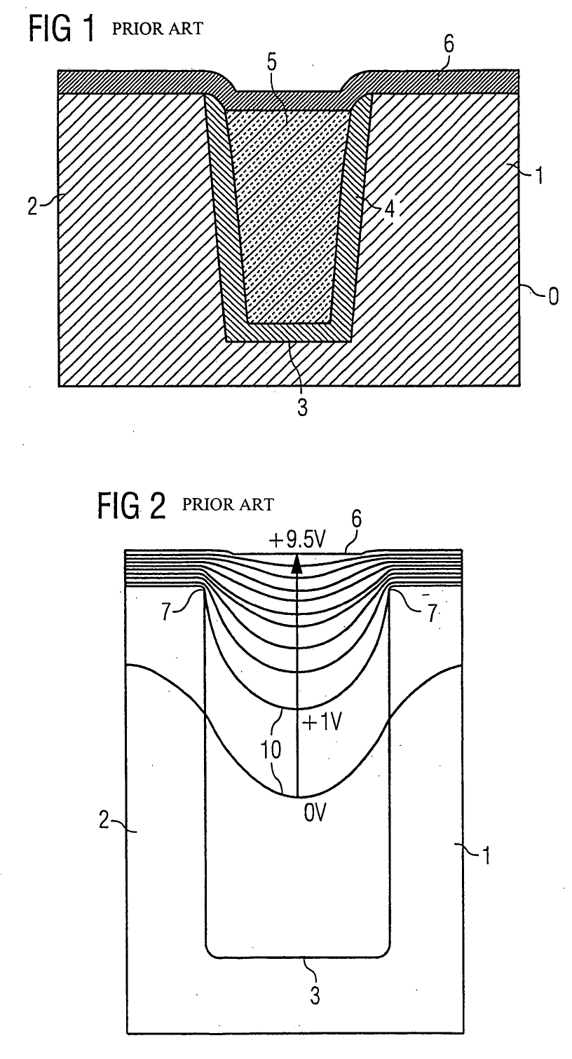

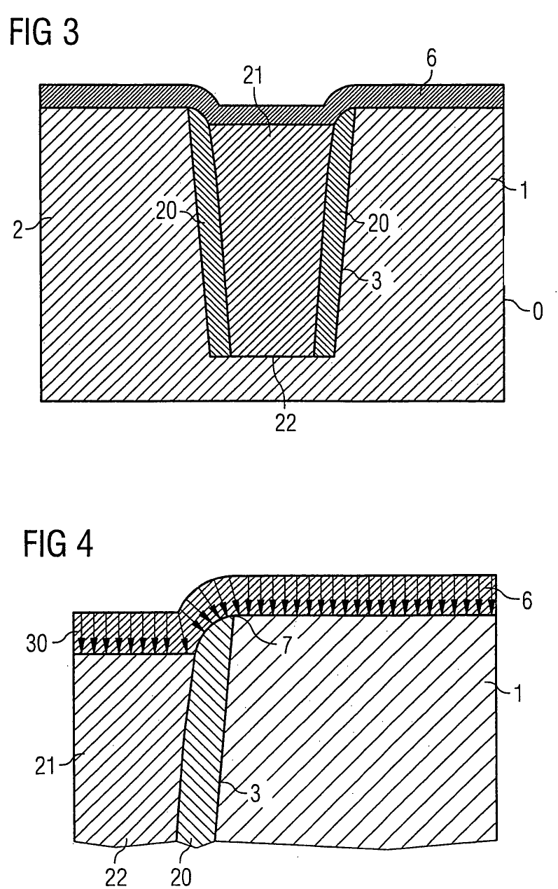

An exemplary embodiment of a trench arrangement will now be described with reference to FIG. 3. In a manner similar to that in FIGS. 1 and 2, a cross section through a substrate 0 is shown, in which the active region of a first transistor 1 is isolated from the active region of a second transistor 2 with the aid of a trench 3. The trench 3 is lined with a relatively thin oxide layer 20 for the purpose of isolating the active regions of the adjacent transistors 1, 2.

In order to prevent the electric field—as shown in FIG. 2—from reaching into the trench and producing an inhomogeneous electric field distribution in particular at the edges 7, the trench 3—in contrast to the prior art—is not filled with insulating oxide but rather with a conductive substance 21, such as, e.g., conductive polysilicon. By virtue of the fact that the trench 3 is filled with a conductive substance 21, the electric field cannot propagate there. By virtue of the insulating substance 20, e.g., an oxide layer, the active regions of the transistors 1, 2 remain electrically insulated from one another despite the conductive substance 21.

In order furthermore to prevent the conductive substance 21 from being charged by induction, a conductive connection of this substance to a defined potential is produced. By way of example, the conductive substance 21 may be electrically conductively connected to the substrate 0. For this purpose, a conductive connection 22 of the trench material 21 to the substrate 0 is provided. In contrast to the prior art, the trench 3 is then not lined with the oxide layer 20 at parts of the bottom. As an alternative, the entire bottom of the trench 3 may be free of oxide. This may be achieved, for example, by etching away the oxide layer 20 at the bottom of the trench 3. The conductive substance 21 may also be connected to other, arbitrary potentials. Instead of the conductive connection 22, a connection may also be effected by means of some other customary method, such as, e.g., bonding or via contact. However, the connection 22 of the conductive substance 21 to the substrate 0, a type of ground contact, obviates additional contacts that would then also have to be connected by complicated methods.

The conductive substance 21 in the trench and the electrical connection 22 of the substance to the substrate 0 result in a matching of the field distribution over the trench and the field distribution over the active regions. The resulting homogenized field distribution is illustrated in FIG. 4, identical reference symbols designating identical subject matters. For the sake of clarity, only the right-hand half of the structure of FIG. 3 is shown. It can clearly be discerned that the magnitude of the electric field 30 is largely constant. Consequently, a reduction of the threshold voltage Vₜₕ is prevented at the edges 7 of the active region 1. As a result, the threshold voltage Vₜₕ of the transistors falls to a lesser extent at small active widths. As a consequence, manufacturing-dictated fluctuations in the active width affect the threshold voltage Vₜₕ of the transistors to a lesser extent. Higher yields or memory densities can be achieved by virtue of the homogenization of the field.

For cells of a flash memory, such as, e.g., NROM or floating gate cells, the homogeneous field 30 ensures a uniform charge injection in the width direction of the cell. As a result, the programming and erasure behavior of the cell is improved, and possibly even the retention behavior is improved.

1. A semiconductor structure comprising:
a semiconductor body;
a trench disposed in the semiconductor body, the trench penetrating from an upper surface of the semiconductor body;
at least one insulating layer disposed along sidewalls of the trench; and
at least one conductive substance filling the trench.

2. The semiconductor structure as claimed in claim 1, wherein the at least one insulating layer covers the trench sidewalls in the form of layers.

3. The semiconductor structure as claimed in claim 2, wherein the at least one conductive substance is electrically conductively connected to the semiconductor body via a conductive connection.

4. The semiconductor structure as claimed in claim 3, wherein the conductive connection is made between the at least one conductive substance at the bottom of the trench and the semiconductor body.

5. The semiconductor structure as claimed in claim 4, wherein the semiconductor body comprises a semiconductor substrate.

6. The semiconductor structure as claimed in claim 1, wherein the at least one insulating layer covers the trench sidewalls and a bottom surface of the trench in the form of electrically insulating layers.

7. The semiconductor structure as claimed in claim 1, wherein the trench is lined with the at least one insulating layer and is filled with the at least one conductive substance.

8. The semiconductor structure as claimed in claim 1, wherein the at least one conductive substance is electrically coupled to a defined potential.

9. The semiconductor structure as claimed in claim 8, wherein the at least one conductive substance is electrically coupled to a ground potential.

10. The semiconductor structure as claimed in claim 8, wherein the at least one conductive substance is electrically coupled to the semiconductor body via a conductive connection.

11. The semiconductor structure as claimed in claim 1, wherein the at least one conductive substance comprises conductive polysilicon.

12. The semiconductor structure as claimed in claim 1, wherein the at least one insulating layer comprises an oxide layer.

13. The semiconductor structure as claimed in claim 1, wherein the trench isolates a first semiconductor component from a second semiconductor component, wherein the first and second semiconductor components are active components.

14. A semiconductor structure comprising:
a semiconductor body;
a transistor disposed in an active region of the semiconductor body, the transistor including a channel having a width of less than 100 nm, the transistor further including a gate separated from the channel by a gate insulating layer; and
an isolation trench abutting the channel of the transistor, the isolation trench being filled with a conductive material that is separated from the active region by an insulating material.

15. The structure of claim 14, wherein the conductive material is electrically coupled to a fixed voltage potential.

16. The structure of claim 15, wherein the insulating material lines sidewalls of the trench and wherein the conductive material is electrically coupled to the semiconductor body at a bottom portion of the trench.

17. The structure of claim 16, wherein the gate extends over a portion of the isolation trench.

18. A method for fabricating an isolation trench, the method comprising:
forming a trench in a substrate;
at least partially lining the trench with an insulating material; and
filling the trench with a conductive material.

19. The method as claimed in claim 18, wherein at least partially lining the trench comprises covering trench walls with the insulating material, the method further comprising electrically conductively connecting the conductive material to the substrate at a bottom portion of the trench via an electrically conductive connection.

20. The method as claimed in claim 19, further comprising forming a transistor in the substrate adjacent to the trench such that the filled trench isolates the transistor from other structures in the substrate, the transistor comprising a channel having a width of less than 100nm, the transistor further including a gate overlying the channel and a portion of the trench, the gate being electrically insulated from the channel and from the conductive material within the trench.
